(19) United States
(12) Patent Application Publication
(10) Pub. No.: US 2026/0015763 A1
(43) Pub. Date: Jan. 15, 2026

(54) SYSTEMS AND METHODS FOR ADDING DOPANT TO AN INGOT PULLER APPARATUS

(71) Applicant: GlobalWafer Co., Ltd., Hsinchu (TW)

(72) Inventors: Yu-Chiao Wu, Frontenac, MO (US); James Dean Eoff, Montgomery City, MO (US); Hsien-Ta Tseng, Miaoli County (TW); Chun-Sheng Wu, Hsinchu City (TW)

(21) Appl. No.: 19/261,080

(22) Filed: Jul. 7, 2025

Related U.S. Application Data
(60) Provisional application No. 63/669,477, filed on Jul. 10, 2024.

(51) Int. Cl. C30B 15/04; C30B 29/06

(52) U.S. Cl. CPC C30B 15/04; C30B 29/06

(57) ABSTRACT

A dopant feeder includes a housing defining an interior chamber and a passageway extending from the interior chamber. The dopant feeder further includes a hub rotatably mounted to the housing. The hub includes a frame and dopant capsules attached to the frame. The dopant capsules are sized to receive a dose of dopant and including a lid that is moveable relative to the frame between a closed position and an open position for releasing the dose of dopant into the passageway.

### CROSS-REFERENCE TO RELATED APPLICATIONS

This application claims the benefit of priority to U.S. Provisional Application No. 63/669,477, filed Jul. 10, 2024, the disclosure of which is incorporated herein by reference in its entirety.

### FIELD

The field of the disclosure relates to ingot puller apparatus for producing single crystal silicon ingots having dopant feeders for adding batches of dopant to the silicon melt.

### BACKGROUND

End-users of single crystal silicon wafers increasingly desire silicon wafers with a narrow range of resistivity. Silicon wafers are typically sliced from single crystal silicon ingots grown using the Czochralski (Cz) method. The electrical properties, such as resistivity, of silicon wafers are built with different dopants (e.g., boron). In the Cz crystal process, solid-phase silicon is melted to the liquid state. Dopants are added to the silicon to achieve a target resistivity range. As liquid silicon continues to solidify in the single-crystal silicon ingot, the net dopant concentration in the liquid silicon is changed (e.g., increased) which can cause the resistivity to fall out of customer specifications.

Counter-doping is used in various solar and semiconductor applications to increase throughput and prime yield of the single crystal silicon ingot. For example, N-type IGBT applications may involve counter-doping with P-type dopants to achieve relatively tight resistivity tolerances (e.g., <+/−13% range or less).

A need exists for apparatus to add multiple batches of dopant to the silicon melt during ingot growth in doping or counter-doping applications to maintain the resistivity of the silicon ingot in the target range.

This section is intended to introduce the reader to various aspects of art that may be related to various aspects of the disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

In one aspect a dopant feeder for adding dopant to a crucible of an ingot puller is provided. The dopant feeder includes a housing defining an interior chamber and a passageway extending from the interior chamber. The dopant feeder further includes a hub rotatably mounted to the housing. The hub includes a frame and dopant capsules attached to the frame. The dopant capsules are sized to receive a dose of dopant and including a lid that is moveable relative to the frame between a closed position and an open position for releasing the dose of dopant into the passageway.

In another aspect a control system for a crystal ingot puller is provided. The control system includes a sensor operable to detect growth of a crystal ingot during a crystal pulling operation and a dopant feeder for adding dopant to a crucible of the crystal ingot puller. The dopant feeder includes a housing defining an interior chamber and a passageway extending from the interior chamber. The passageway connects the interior chamber with the crucible. The dopant feeder further includes a hub rotatably mounted to the housing, the hub including a frame and dopant capsules attached to the frame. The dopant capsules are sized to receive a dose of dopant and include a lid that is moveable relative to the frame between a closed position and an open position for releasing the dose of dopant into the passageway. The control system further includes a controller in communication with the dopant feeder and the sensor, wherein the controller is configured to receive, from the sensor, a signal indicating the detected growth of the crystal ingot and automatically control the dopant feeder to dispense a dose of dopant into the crucible based on the received signal.

In yet another aspect, an ingot puller apparatus for producing a doped single crystal silicon ingot is provided. The ingot puller apparatus includes an ingot puller outer housing, an ingot puller inner chamber formed within the ingot puller outer housing, a crucible disposed within the ingot puller inner chamber, and a dopant feeder for adding dopant to the crucible. The dopant feeder includes a housing defining an interior chamber and a passageway extending from the interior chamber, the passageway connecting the interior chamber with the crucible. The dopant feeder further includes a hub rotatably mounted to the housing. The hub includes a frame and dopant capsules attached to the frame. The dopant capsules are sized to receive a dose of dopant and include a lid that is moveable relative to the frame between a closed position and an open position for releasing the dose of dopant into the passageway.

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above- described aspects of the present disclosure, alone or in any combination.

### BRIEF DESCRIPTION OF THE DRAWINGS

FIG. 1 is a cross-section of an ingot puller apparatus having a dopant feed system;

FIG. 2 is a detailed cross-section of the ingot puller apparatus and dopant feed system of FIG. 1;

FIG. 3 is a perspective view of a dopant feeder for use with the ingot puller apparatus having a dopant feed system of FIG. 1;

FIG. 4 is another perspective view of the dopant feeder of FIG. 3;

FIG. 5 is a front view of the dopant feeder of FIG. 3;

FIG. 6A is a perspective view showing a driving module of the dopant feeder of FIG. 3;

FIG. 6B is a perspective view of a fork of the driving module shown in FIG. 6A;

FIG. 7 is a perspective view of a doping hub of the dopant feeder of FIG. 3;

FIG. 8 is another perspective view of the doping hub of FIG. 7 rotated to a first position;

FIG. 9 is another perspective view of the doping hub of FIG. 7 rotated to a second position;

FIG. 10 is another front view of the dopant feeder of FIG. 3;

FIG. 11 is a perspective view of the dopant feeder of FIG. 3, showing a saucer plate of the dopant feeder;

FIG. 12 is a perspective view of a dopant loading system including a loading assembly and the doping hub shown in FIG. 7;

FIG. 13 is an enhanced view of a portion of the dopant loading system of FIG. 12;

FIG. 14 is a cross section of a portion of the dopant loading system of FIG. 12;

FIG. 15 is a perspective view showing a first step of an installation process for installing the doping hub in the loading assembly of FIG. 12;

FIG. 16 is a perspective view showing a second step of the installation process;

FIG. 17 is a perspective view showing a third step of the installation process;

FIG. 18 is a perspective view showing a first step of a dopant loading process using the dopant loading system of FIG. 12;

FIG. 19 is a perspective view showing a second step of the dopant loading process;

FIG. 20 a perspective view showing a third step of the dopant loading process; and

FIG. 21 is a schematic diagram showing a control system for controlling the ingot puller apparatus of FIG. 1.

Corresponding reference characters indicate corresponding parts throughout the drawings.

### DETAILED DESCRIPTION

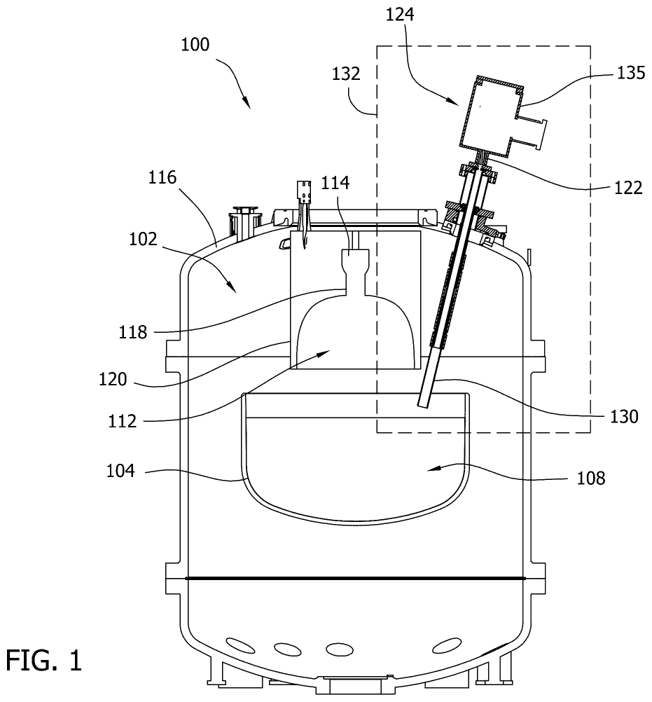

Embodiments of the present disclosure relate to dopant feeders for adding dopant to a silicon melt held within a crucible of an ingot puller apparatus. An example ingot puller apparatus 100 in which the dopant feeders of the present disclosure may be used is shown in FIG. 1. The ingot puller apparatus 100 includes an ingot puller outer housing 116 that defines an ingot puller inner chamber 102 within the housing 116. A crucible 104 is disposed within the ingot puller inner chamber 102. The crucible 104 contains the silicon melt 108 from which the silicon ingot 112 is pulled. The ingot 112 is shrouded by a heat shield 120.

The ingot puller apparatus 100 includes a dopant feed system 132. The dopant feed system 132 includes a dopant feeder 124 and dopant tube 130 that extends through the housing 116 (and in some instances through a reflector) for adding solid-phase dopant to the crucible 104. Solid-phase dopant passes through the dopant tube 130 (and may at least partially sublime during transport) to contact the melt 108 to cause the melt 108 to be doped. The dopant tube 130 includes an inlet 122 disposed exterior to the ingot puller inner chamber 102 and an outlet 126 disposed in the ingot puller inner chamber 102 and positioned relatively near the surface of the melt 108.

The dopant feeder 124 is disposed exterior to the ingot puller inner chamber 102. The dopant feeder 124 includes a dopant feeder housing 135 and one or more dopant capsules 248 (discussed further below) disposed within the housing 135 for adding solid-phase dopant to the melt 108. The dopant feed system 132 may include an isolation valve (not shown) below the dopant feeder 124 to allow the dopant feeder 124 to be isolated and to return to atmospheric pressure to allow dopant to be added to the dopant feeder. The dopant feeder housing 135 is external to the ingot puller outer housing 116.

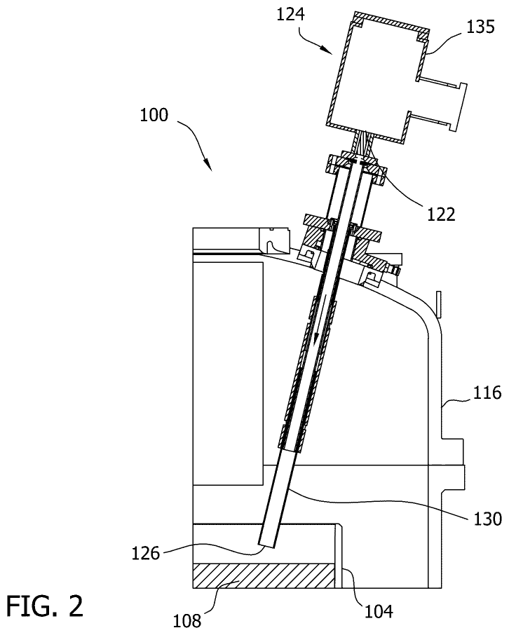

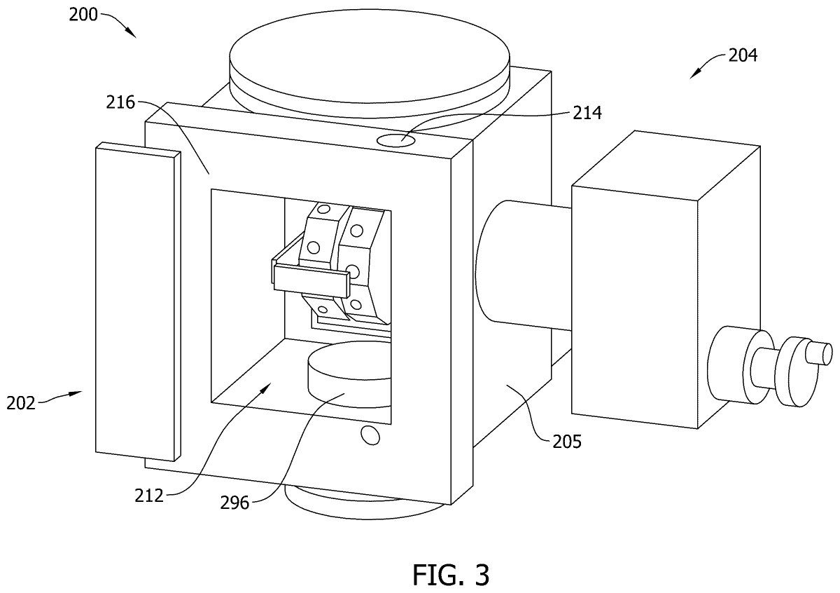

FIGS. 3-12 show an example dopant feeder 200 for use with the ingot puller apparatus 100 shown in FIGS. 1 and 2.

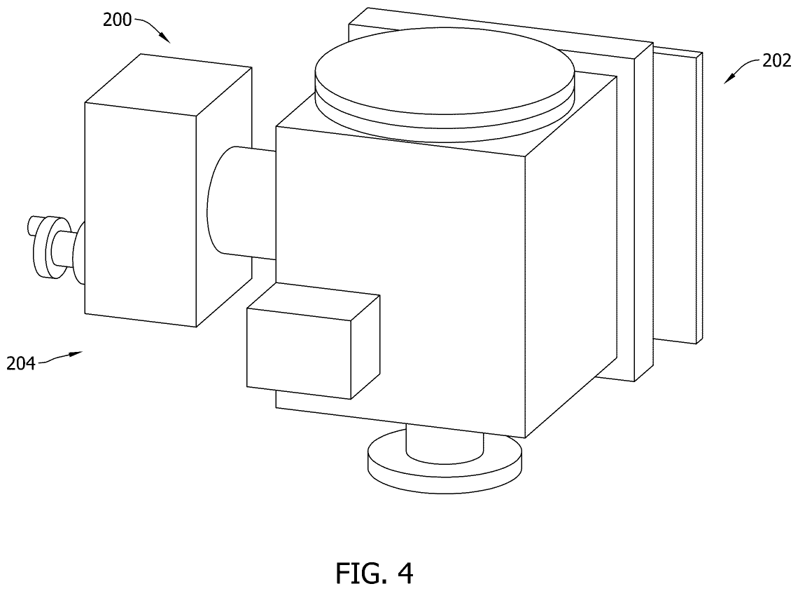

Referring to FIGS. 3 and 4, the dopant feeder 200 is an automatic solid-phase counter doper and includes a doping module 202 and a driving module 204. The doping module 202 is a subsystem of the dopant feeder 200 that adds a dose of dopant (also referred to herein as a “dopant chip”, “dopant chip”, or “dopant”)) to the liquid silicon melt 108 (shown in FIG. 1). The dopant module 202 includes a housing 205 that defines an interior chamber 212 and a passageway 296 extends from the interior chamber 212. The passageway 296 connects the interior chamber 212 to the silicon melt 108 (e.g., by the tube 130 shown in FIG. 1). The driving module 204 is a subsystem of the dopant feeder 200 used to drive, or more specifically, rotate the doping module 202 to trigger release of the dopant chips from the doping module 202.

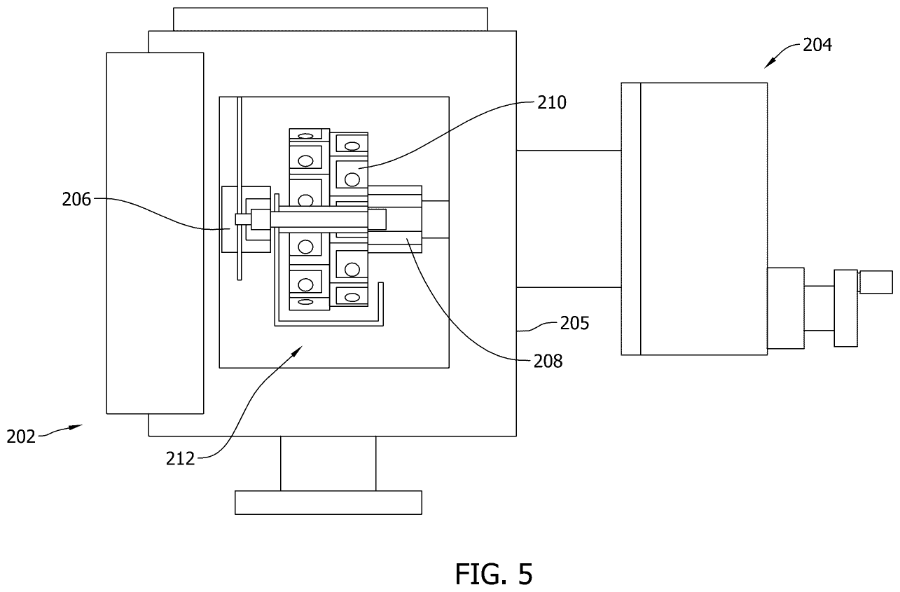

As shown in FIG. 5, the doping module 202 includes a holder 206, a rotator 208, and a doping hub 210 which are placed inside the chamber 212. The chamber 212 is a vacuum chamber operable to maintain air pressure inside the chamber 212 at a level lower than the atmospheric pressure and reach the crystal growth pressure.

The holder 206 is a fixed support attached to the housing and used to hold the doping hub 210. The rotator 208 is driven by the driving module 204 and used to rotate the doping hub 210 to release dopant chips from the doping hub 210 and into the melt 108 (shown in FIG. 1).

Referring to FIG. 3, the dopant feeder 200 includes a first sensor 214. The first sensor 214 is a motion or proximity sensor that detects a status of a chamber door 216, e.g., open or closed. The automatic doping operation is prevented when the chamber door 216 is open.

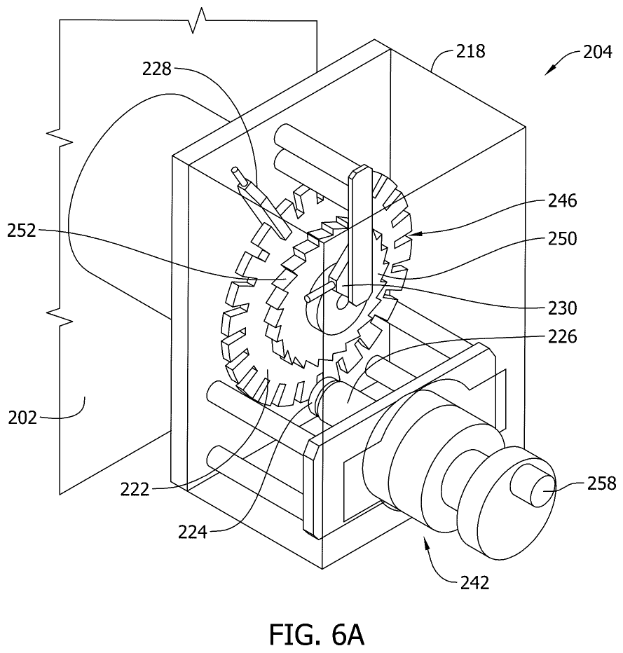

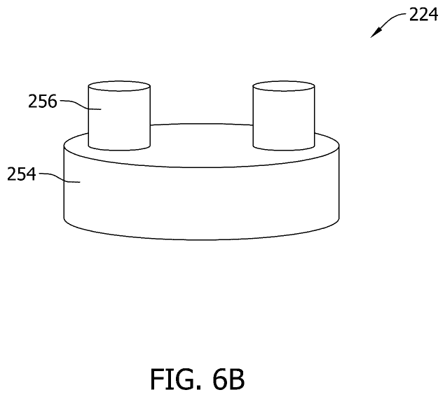

Referring now to FIG. 6A, the driving module 204 is illustrated. The driving module 204 drives rotation of the doping hub 210 (shown in FIG. 3) to release dopant from the doping hub 210.

The driving module 204 includes a drive housing 218 attached to the vacuum chamber 212. The drive housing 218 may be transparent or opaque. In FIG. 6, the drive housing 218 is shown as being transparent to reveal internal components of the driving module 204.

The driving module 204 further includes a driving wheel 222, a fork 224, a clutch 226, a second sensor 228, and a third sensor 230 each positioned within the drive housing 218. A drive 242, a rotary air cylinder in the example, is connected to the drive housing 218 and provides power rotate the driving wheel 222. The driving wheel 222 connects to the rotator 208 (shown in FIG. 5) of the doping module 202 via a shaft (not shown).

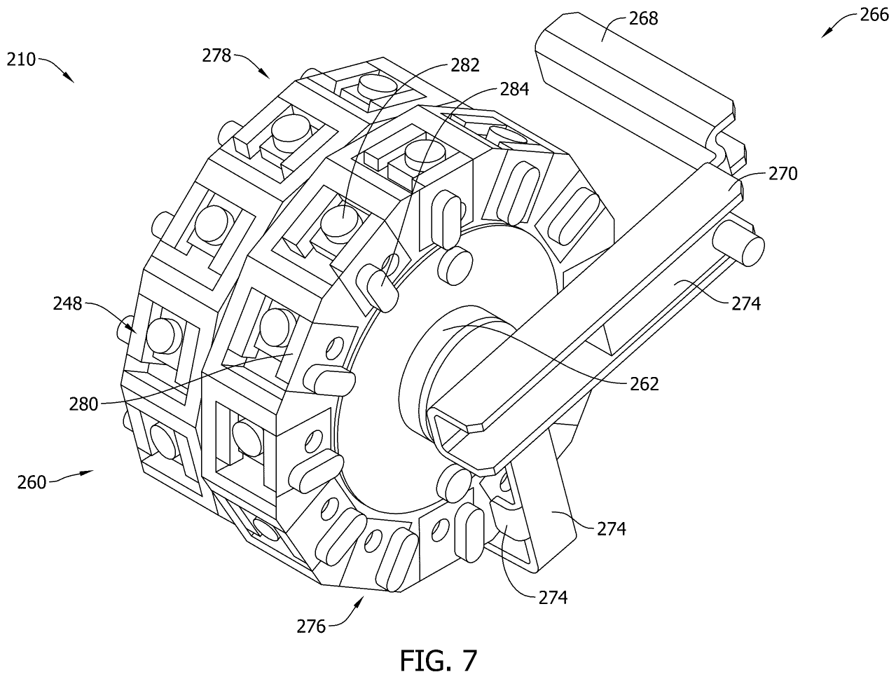

The driving wheel 222 defines slots 246 positioned around a circumference of the driving wheel 222. In particular, the number of slots 246 of the driving wheel 222 is equal to a number of the dopant capsules 248 (shown in FIG. 7) on the doping hub 210, plus one additional home position slot. The driving module 204 rotates the doping hub 210 in discrete increments, also referred to herein as “steps”, with each slot of the driving wheel corresponding to a single rotation increment.

The driving wheel 222 includes a ratchet gear 250 including teeth 252 extending radially outward around a circumference of the ratchet gear 250. The teeth 252 are shaped to restrict rotation in a direction opposite to a driving rotational direction of the driving wheel 222. For example, in the example of FIG. 6, during a doping cycle the driving wheel 222 is rotated in a clockwise direction and the teeth 252 of the ratchet gear 250 engage a pawl (e.g., a spring-loaded pivotable lever, not shown) in the driving module 204 to restrict counter-clockwise rotation of the driving wheel 222. In the example of FIG. 6, the ratchet gear 250 and the driving wheel 222 are attached so as to form a single-piece, though in other embodiments the ratchet gear 250 may be formed as a separate piece and connected to the driving wheel 222.

FIG. 6B shows a schematic of the fork 224 shown in FIG. 6A. Referring to FIG. 6B, the fork 224 includes a base 254 having a generally cylindrical shape and a pair of prongs 256 extending outward from an end of the base 254. The prongs 256 are shaped and positioned in correspondence with the slots 246 to extend into the slots 246 on the driving wheel 222 (shown in FIG. 6A). The prongs 256 are positioned on the base 254 to be diametrically opposed, such that the prongs 256 are each equidistant from a radial center of the base 254 and are positioned at approximately a 180-degree offset from each other on the base 254. As shown in FIG. 6B, the prongs 256 each have a cylindrical shape though in other embodiments the prongs 256 may have any suitable shape and size that enables the prongs 256 to engage the slots 246 of the driving wheel 222 as described. In other embodiments, the fork 224 may have a single prong 256 or more than two prongs 256. For example, in one embodiment, the fork 224 has four prongs 256 and is rotated a quarter turn (i.e., 90-degrees) during each actuation of the rotary cylinder.

Referring to FIGS. 6A and 6B, during use the rotary air cylinder 242 rotates the clutch 226 and fork 224 a half-turn (i.e., approximately 180 degrees). The fork 224 is sized to engage the slots 246 on the driving wheel 222 such that, in response to the rotation of the fork 224, the driving wheel 222 rotates from the current slot to the next slot (i.e., a single slot position). The fork 224 transfers the energy from the rotary air cylinder 242 into rotational motion of the driving wheel 222 and the doping hub 210. Prior to rotation of the fork 224, one of the prongs 256 (shown in FIG. 6B) is received in a slot 246 of the driving wheel 222 while the other prong 256 is positioned outside of (e.g., below) the slot 246. As the fork 224 is rotated, the prong 256 received within the slot 246 engages and rotates the driving wheel 222 until the prong 256 is rotated out of the slot 246. Simultaneously, the other prong 256 is moved into the adjacent slot 246 and continues driving the rotation of the driving wheel 222 until the fork 224 has been rotated a half-turn and the driving wheel 222 is rotated one step (i.e., one slot position).

After the fork 224 is rotated, the clutch 226 is disengaged with the fork 224 and the rotary air cylinder 242 reversely rotates back to a zero- degree position for the next doping. When the rotary air cylinder 242 is rotated back to a zero-degree position, the fork 224 and driving wheel 222 do not rotate because the clutch 226 does not transmit the reverse rotation.

The driving module 204 further includes a knob 258 allowing for controlling the doping cycle manually. In the driving module 204, the second sensor 228 detects incrementing of the doping hub 210 and is used to count the number of doping cycles. The third sensor 230 detects a home position slot of the doping hub 210 as the doping hub 210 is rotated.

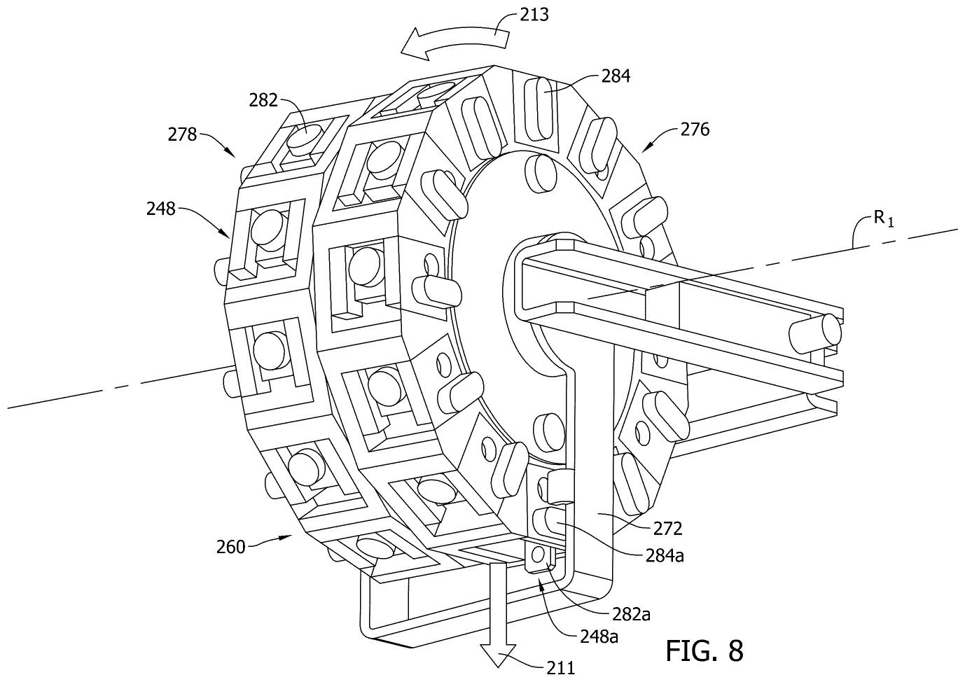

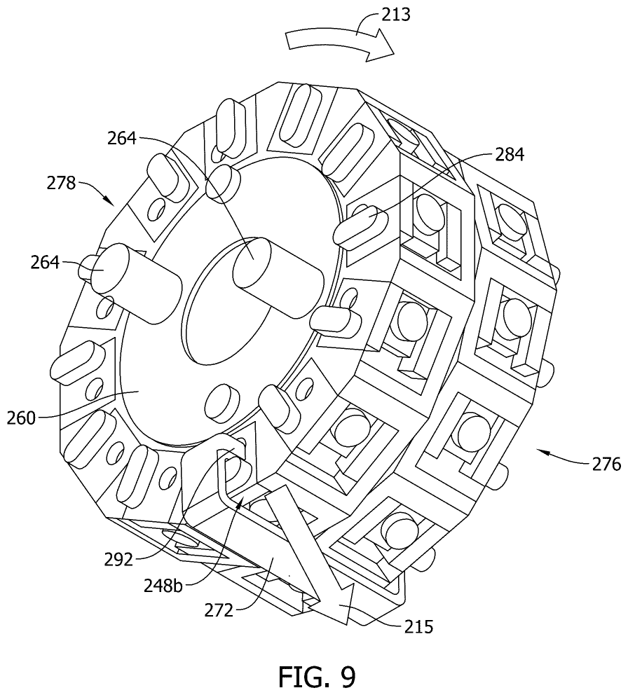

FIGS. 7-9 show the doping hub 210 of the feeder 200 of FIGS. 3-6. Referring to FIG. 7, the doping hub 210 includes a wheel frame 260 (also referred to herein as a “frame”) mounted on a shaft 262. The shaft 262 defines a rotational axis R₁ of the wheel frame 260 (shown in FIG. 8). A pair of driven prongs 264 (shown in FIG. 9) are attached to the wheel frame 260 for driving rotation of the reel frame about the shaft 262. The rotator 208 (shown in FIG. 5) includes a connector (not shown) that attaches to the driven prongs 264 for rotating the wheel frame 260 on the shaft 262. In other embodiments, the shaft 262 is drivingly connected to the rotator 208 and rotates the wheel frame 260 under rotation of the rotator 208.

Referring to FIG. 7 doping hub 210 includes a mounting assembly 266 attached to the wheel frame 260. During use, the mounting assembly 266 attaches the doping hub 210 to the vacuum chamber 212 (shown in FIG. 5) and the wheel frame 260 rotates relative to the mounting assembly 266. The mounting assembly 266 includes a handle 268, a mounting bar 270 connected to the handle 268, an opener bracket 272 connected to the mounting bar 270, and a lock 274 connected to the mounting bar 270.

The lock 274 is moveable to engage with or disengage with the wheel frame 260. When the lock 274 is engaged with the wheel frame 260, rotation of the wheel frame 260 is prevented. During use, the lock 274 is actuated when the doping hub 210 is loaded into the vacuum chamber 212 and is unlocked after the doping hub 210 is installed in the vacuum chamber 212. The lock 274 is slidable along the mounting bar 270 to lock the wheel frame 260. The handle 268 is shaped to enable an operator to hold the doping hub 210 by hand during removal and/or installation of the doping hub 210 within the vacuum chamber 212.

The wheel frame 260 defines a pair of rounds including a first round 276 and a second round 278. The first round 276 and the second round 278 are each attached to the shaft 262 and rotate with the shaft 262 as a single-piece. The first round 276 and the second round 278 are rotationally offset relative to one another. As described in greater detail herein, the rotational offset of the first round 276 and the second round 278 facilitates releasing a single dose of dopant from one of the rounds in alternating fashion during each step increment. In other embodiments the wheel frame 260 may include a single round or three or more rounds.

The doping hub 210 includes dopant capsules 248 attached to the wheel frame 260 and positioned circumferentially about the wheel frame 260. Each dopant capsule 248 is sized to contain a single dose of dopant therein (e.g., a single dopant chip). Each round 276, 278 of the wheel frame 260 includes dopant capsules 248 positioned around the entire outer circumference of the rounds 276, 278. The capsules 248 are each attached to the wheel frame 260 by a capsule frame 280. The wheel frame 260 defines openings (not shown) that receive the capsule frames 280 and the capsules 248 therein.

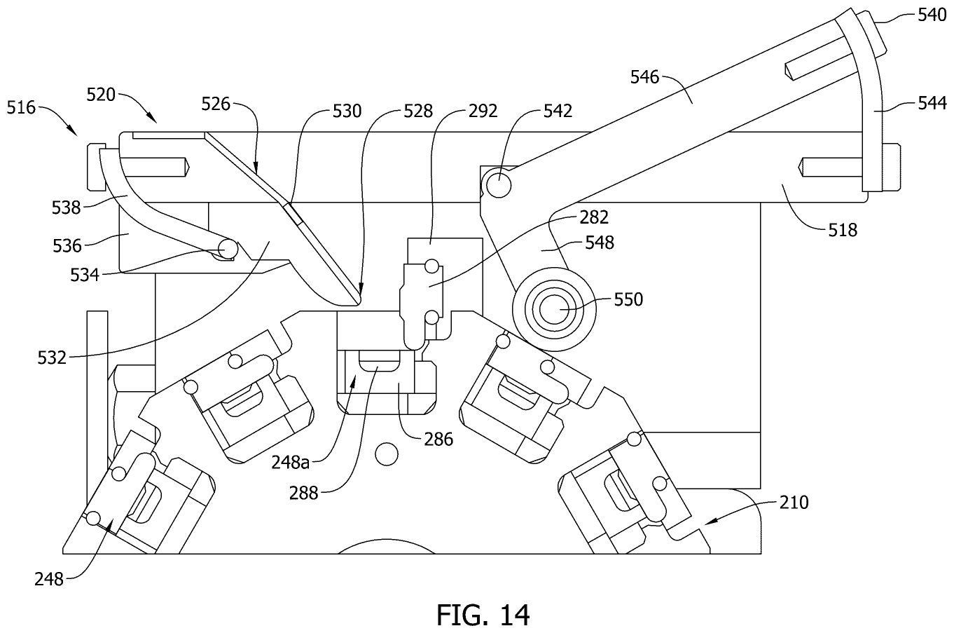

The dopant capsules 248 each include a lid 282 and a lever 284 connected to the lid 282. The lid 282 is positioned along the outer circumference of the wheel frame 260 and the lever 284 is positioned on an end of the wheel frame 260. The lid 282 is sized to cover a capsule body 286, and specifically a receptacle 288 of a capsule body 286 (shown in FIG. 14) that receives a dose of dopant therein. In the example embodiment, the dopant capsules 248 each receive the same amount of dopant having the same composition during use, though in other embodiments different dose amounts of dopants and/or dopant compositions may be provided to the dopant capsules. For example, in some embodiments, some of the dopant capsules 248 are loaded with a single dopant chip while other capsules may be loaded with two or more dopant chips.

Referring to FIG. 8, the lids 282 of the dopant capsules 248 are pivotable on the wheel frame 260 between a closed position and an open position. For example, in FIG. 8, each of the lids 282 of the dopant capsules 248 is in the closed position and the lid 282a of the dopant capsule 248a is in an open position. The lids 282 are freely hinged on the wheel frame 260, though in some embodiments, the lids 282 may be biased to the closed position by an internal biasing device (e.g., a spring, not shown). In the closed position, the lids 282 are oriented tangentially relative to the frame 260, facilitating securing the dose of dopant within the capsules 248. In the closed position, the levers 284 are oriented to extend generally radially of the wheel frame 260. In the open position, the lever 284a is oriented to extend tangentially of the wheel frame 260 and the lid 282a is oriented to extend radially of the wheel frame 260, allowing the dose of dopant within the capsule 248a to fall under gravity in the downward direction, indicated by the arrow 211.

The doping hub 210 contains a pair of opener tabs 290, 292 for moving the dopant capsules 248 from the closed position to the open position. In the example of FIGS. 8 and 9, the opener tabs 290, 292 are positioned on the opener bracket 272 of the doping hub to engage levers 284 on one of the rounds 276, 278 of the doping hub 210 respectively. The opener tabs 290, 292 are axial projections that project axially (i.e., parallel to the rotational axis R₁ of the wheel frame 260) toward the wheel frame 260 and are positioned to be aligned with the levers 284 of a lowermost dopant capsule 248 as the wheel frame 260 is rotated. A first opener tab 290 (shown in FIG. 8) is positioned to engage the levers 284 of the first round 276. A second opener tab 292 (shown in FIG. 9) is positioned to engage the levers 284 of the second round 278. The opener bracket 272 is connected to the shaft 262 and the handle 268 to be fixed in position while the wheel frame 260 is rotated. In other embodiments, the opener tabs 290, 292 may be positioned on any suitable fixed structure within the vacuum chamber 212 and in some embodiments may be attached to a wall of the chamber 212.

As shown in FIG. 8, the dopant capsule 248a is opened by the first opener tab 290. As the wheel frame 260 is rotated to a next step in the rotational direction, indicated by the arrow 213, the lever 284a is moved to a position clear of the opener tab 290. In embodiments in which the dopant capsules 248 include a biasing device (not shown) after the lever 284a is clear of the opener tab 290, the lid 282a is biased to the closed position. In other embodiments, the lid 282a may remain open or at least partially open throughout the remainder the doping operation.

FIG. 9 shows the doping hub 210 at a step subsequent to the step shown in FIG. 8, with the mounting bar 270 and handle 268 removed. As shown in FIG. 9, the dopant capsule 248b on the second round 278 is moved to the open position, allowing a dose of dopant within the capsule 248 to be released in the direction 215. As shown in FIG. 9, only the dopant capsule 248b is in the open position while all other dopant capsules 248 on the doping hub 210 are in the closed position. The rotational offset of the first round 276 and the second round 278 facilitates opening dopant capsules 248 from the first round 276 and the second round 278 in an alternating fashion, such that only a single dopant capsule 248 is opened for each rotation step.

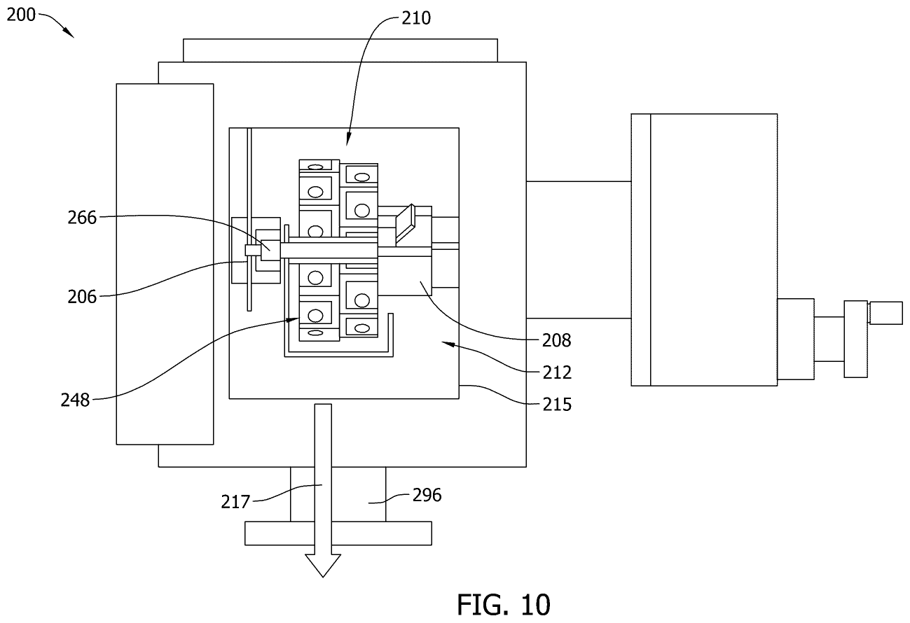

FIG. 10, shows an example doping operation. As shown in FIG. 10, the doping hub 210 is connected to the housing by the rotator 208, which engages the driven prongs 264 (shown in FIG. 9) of the doping hub 210, and the holder 206 which engages the mounting assembly 266 of the doping hub 210.

During use, as the doping hub 210 is rotated, each increment of rotation of the doping hub 210 causes one of the capsules 248 to release a dose of dopant, which falls to the passageway 296 in the direction 217. As the doping hub 210 is rotated, the driven prongs 264 are rotated within the vacuum chamber 212 while the mounting assembly 266 of the doping hub 210 remains fixed.

In the example embodiment, the doping hub 210 may only be installed and/or removed from the vacuum chamber when the doping hub 210, and specifically the driven prongs 264 (shown in FIG. 9) of the doping hub 210, are in a specific loading orientation relative to the mounting bar 270 (shown in FIG. 7). The step or rotational increment at which the doping hub 210 may be loaded/unloaded into the vacuum chamber 212 is referred to as the “home position”. In the example, the doping hub 210 does not include a capsule 248 corresponding with the home position and the home position is the only rotational increment at which a dose of dopant is not released from the doping hub 210. In other embodiments, such as embodiments where the shaft 262 drives rotation of the wheel frame 260, the doping hub 210 may be installed and/or removed at any rotational increment.

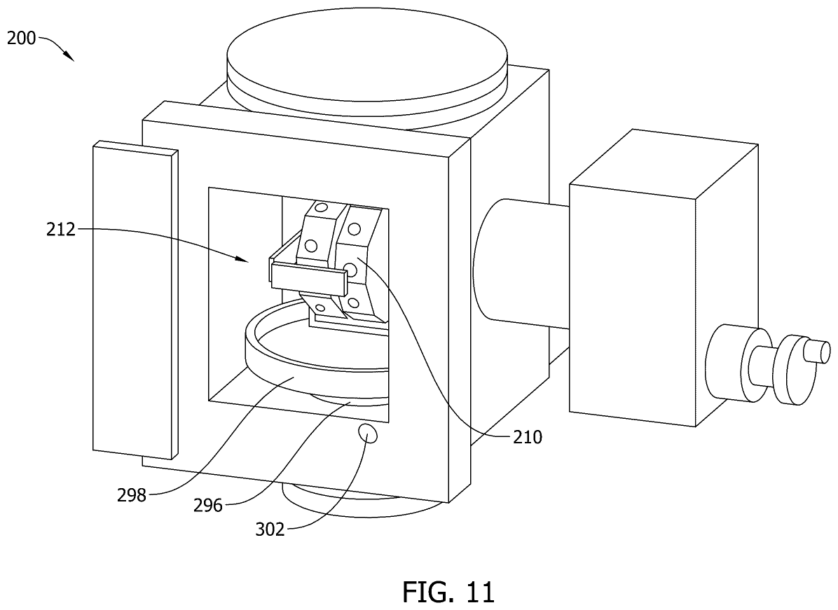

FIG. 11 shows the dopant feeder 200 with a saucer plate 298 received within the vacuum chamber 212. The saucer plate 298 may be installed after doping is completed and used to catch any remaining dopant chips remaining within the doping hub 210, as the doping hub 210 is rotated back to the home position for removal from the vacuum chamber. For example, in some crystal growth operations, not all doping chips from each of the doping capsules 248 may be added to the melt. In the event that some dopant chips remain within the doping hub 210 after crystal growth operations (i.e., the doping hub was not fully rotated during doping) the saucer plate 298 is inserted into the vacuum chamber 212 and used to capture any remaining dopant chips capsules after the crystal growth ends. The saucer plate 298 is positioned below the doping hub 210 and above the passageway 296 as shown in FIG. 11. A fourth sensor 302 detects the saucer plate 298 within the vacuum chamber 212 to prevent the doping process from being conducted if the saucer plate 298 is positioned below the doping hub 210 (e.g., if the saucer plate 298 is mistakenly left in the vacuum chamber 212 during a crystal growth operation).

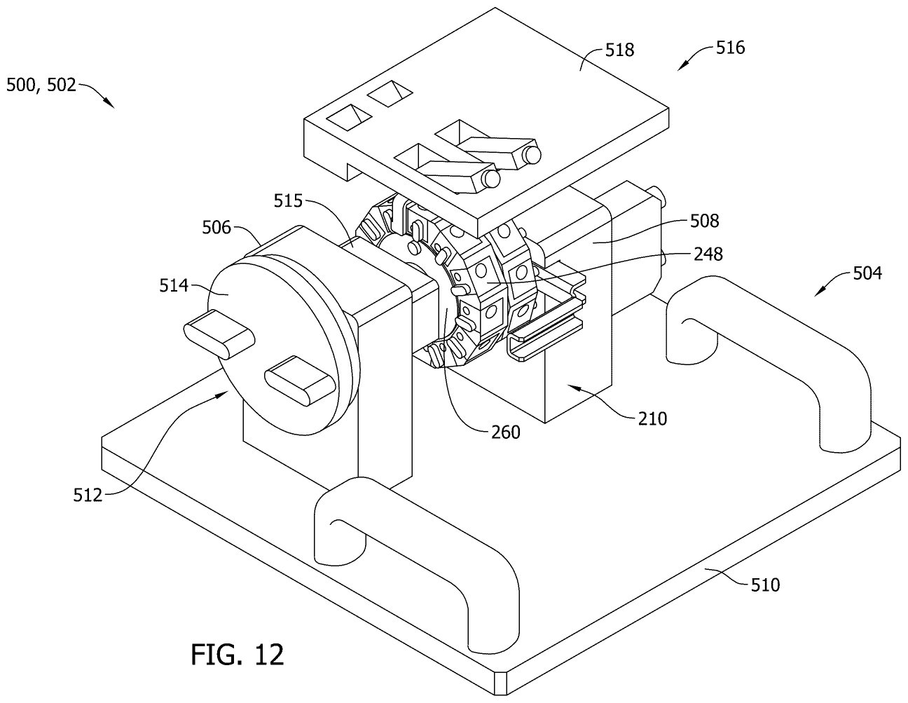

FIGS. 12-20 show a dopant loading system 500 including a loading assembly 502 for loading dopant chips into the doping hub 210, and more specifically, into the dopant capsules 248 of the doping hub 210.

Referring to FIG. 12, the loading assembly 502 includes a hub mount 504 including a first column 506 and a second column 508 connected to a base platform 510. The hub mount 504, and specifically the first column 506 and the second column 508, rotatably support the doping hub 210 allowing for rotation of the doping hub 210 within the hub mount 504. The first column 506 and the second column 508 are spaced on the base platform 510 to receive the doping hub 210 between the first column 506 and the second column 508.

The loading assembly 502 includes a transmission 512 connected to the hub mount 504 for rotating the doping hub 210 within the hub mount 504. The transmission 512 includes a driving knob 514 (alternatively a “drive”) and a loading rotator 515 connected to the driving knob 514. The driving knob 514 and the loading rotator 515 are each connected to and supported on the first column 506. The loading rotator 515 engages the driven prongs 264 (shown in FIG. 9) of the wheel frame 260 for rotating the doping hub 210. In the example embodiment the driving knob 514 is a manual drive that is hand manipulated by an operator to rotate the doping hub 210. In other embodiments, the loading assembly 502 may include an automated actuator such as, but not limited to, a motor, pneumatic actuator, and/or a hydraulic actuator.

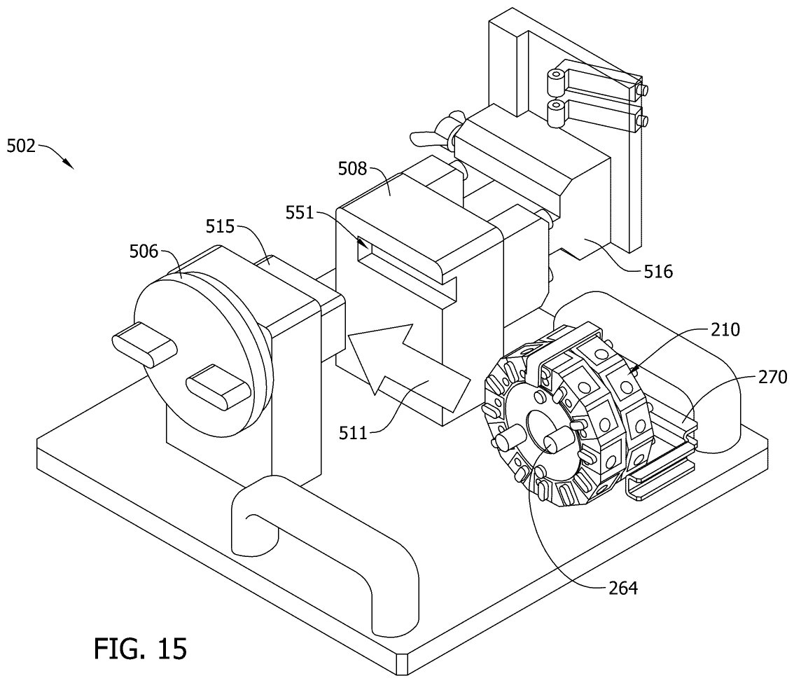

The loading assembly 502 includes a loading stage 516 connected to and supported by the hub mount 504. Specifically, the loading stage 516 is pivotably attached to the second column 508 and is pivotable between a first position (shown in FIG. 15) for connecting the doping hub 210 to the hub mount 504, and a second position, as shown in FIG. 12, for loading dopant into the doping hub 210. The loading stage 516 includes a loading wall 518 that extends over the doping hub 210 when the doping hub 210 is received in the loading assembly 502 and the loading stage 516 is in the second position.

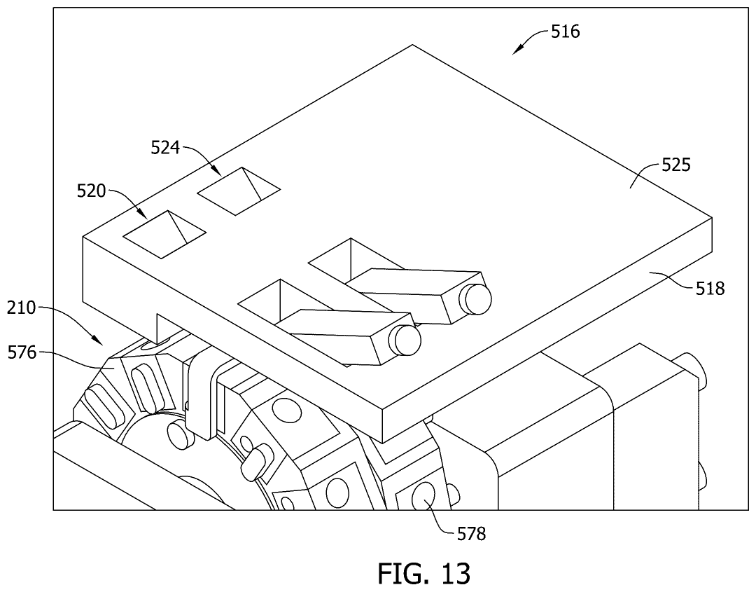

Referring to FIG. 13, the loading stage includes a first inlet 520 and a second inlet 522 that are accessible at an exterior surface 525 of the loading wall 518. The first inlet 520 and the second inlet 522 are each sized to receive a dose of dopant (e.g., a dopant chip) therein. The first inlet 520 is used for loading dopant into the first round 276 of the doping hub 210 and the second inlet 522 is used for loading dopant into the second round 278 of the doping hub 210.

FIG. 14 is a cross section of the loading stage 516 and the doping hub 210 showing a first channel 526 of the loading stage 516 connected with the first inlet 520, shown in FIG. 13. It should be understood that the loading assembly 502 includes a second channel (not shown) that is substantially the same as the first channel 526 described herein and that is in connected with the second inlet 522 (shown in FIG. 13).

Referring to FIG. 14, the channel 526 extends through the loading stage 516 from the inlet 520 to an outlet 528. The outlet 528 is positioned to be aligned with each of the doping capsules 248 as the doping hub 210 is rotated within the hub mount 504 for loading dopant into each of the dopant capsules 248. For example, as shown in FIG. 14, the outlet 528 is aligned with the dopant capsule 248a. In FIG. 14, a dose of dopant 530 (also referred to herein as a “dopant chip”) is shown approximately midway through the channel 526. The channel 526 guides the dopant chip 530 falling under gravity to the outlet 528 and into the dopant capsule 248a.

During use, as the doping hub 210 is rotated, the lids 282 of the dopant capsules 248 are configured to be opened by the opener tab 292 in substantially the same manner as described above with respect to FIGS. 7-9. The opener tab 290 engages the levers 284 (shown in FIG. 7) of the dopant capsules 248, causing the lids 282 to rotate to the open position. The loading assembly 502 receives the doping hub 210 in an orientation where the opener tab 292 is positioned adjacent to the outlet 528, such that the dopant capsule 248 is opened when rotated into alignment with the outlet 528.

The loading stage 516 includes a slide 532 that at least partially defines the channel 526 and extends to the outlet 528. The slide 532 is pivotably attached by a first hinge 534 to an interior wall 536 of the loading stage 516 that depends from the loading wall 518. The slide 532 is operable to pivot about the first hinge 534 between a lowered position, shown in FIG. 14, and a raised position as the lid 282 on the capsule 248 is raised to provide clearance for the lid 282 to be moved to the open configuration. The slide 532 rotates about a rotational axis extending through the first hinge 534 (i.e., into the page in FIG. 14). For example, in the lowered position the slide 532 extends to a position beyond a rotational arc of the lid 282 to facilitate guiding the dopant chip 530 closely into the receptacle 288. As doping hub 210 is rotated and the lid 282 is raised, the lid 282 contacts the slide 532 as the lid 282 is opened and the slide 532 pivots about the hinge 534 (e.g., in a counter-clockwise direction in the view of FIG. 14) from the lowered position to a raised position. As the lid 282 opened and clears the slide 532, the slide 532 is free to rotate back to the lowered position shown in FIG. 14. In the example of FIG. 14, a first biasing device 538 is connected to the slide 532 and biases the slide 532 to the lowered position. The first biasing device 538 in the example embodiment is a flexible O-ring that is attached to the loading wall 518 and to the slide 532. In other embodiments, any other suitable biasing device may be used. In yet further embodiments, the slide 532 may not include a biasing device and instead may fall under gravity to the lowered position after the lid 282 has cleared the slide 532.

The loading stage 516 includes a closing finger 540 pivotably attached to the loading wall 518 by a second hinge 542. The closing finger 540 is operable to pivot about the second hinge 542 for urging an opened lid 282 of a dopant capsule 248 to the closed position, as shown in FIG. 14. In particular, the closing finger 540 is rotatable about a rotational axis extending through the second hinge 542 (i.e., into the page in FIG. 14). A second biasing device 544 is connected to the closing finger 540 and the loading wall 518 and biases the closing finger 540 to engage the lids 282 of the dopant capsules 248 as the doping hub 210 is rotated.

The closing finger 540 has a generally “L” shaped profile including a first bar 546 and a second bar 548 connected to the first bar 546 and oriented generally perpendicular to the first bar 546. The closing finger 540 is connected to the second hinge 542 at an intersection of the first bar 546 and the second bar 548. A roller closing member 550 is attached to the second bar 548 at a distal end of the second bar 548. The closing member 550 contacts the lids 282 to urge the lids 282 to the closed position after the dose of dopant has been received in the receptacles 288.

FIGS. 15-17 show steps of an installation process of installing the doping hub 210 onto the loading assembly 502. Referring to FIG. 15, at a first step the loading stage 516 is rotated to an opened position, providing clearance for insertion of the doping hub 210. The doping hub 210 is inserted in between the first column 506 and the second column 508 along the direction 511. The second column 508 defines a recess 551 that receives the mounting bar 270 of the doping hub 210 therein. The loading rotator 515 connects to the driven prongs 264 of the doping hub 210 by a connector (not shown) shaped in correspondence with the driven prongs 264.

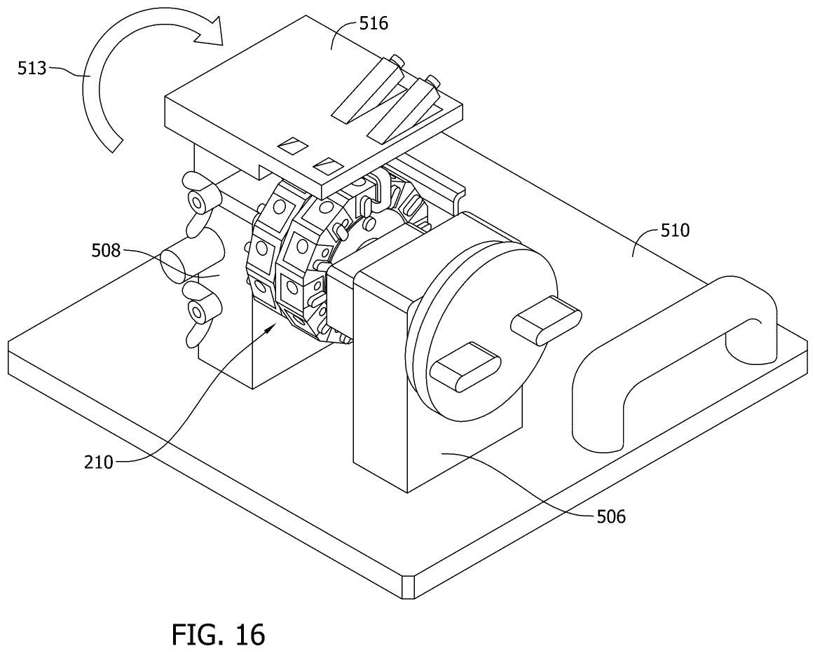

Referring to FIG. 16, after the doping hub 210 is connected to the first column 506 and the second column 508, the doping hub 210 is suspended above the base platform 510 and supported by the first column 506 and the second column 508. At a second step of the installation process, the loading stage 516 is rotated along the direction 513 to the lowered position. In the lowered position, the loading stage 516 extends above and at least partially covers the doping hub 210.

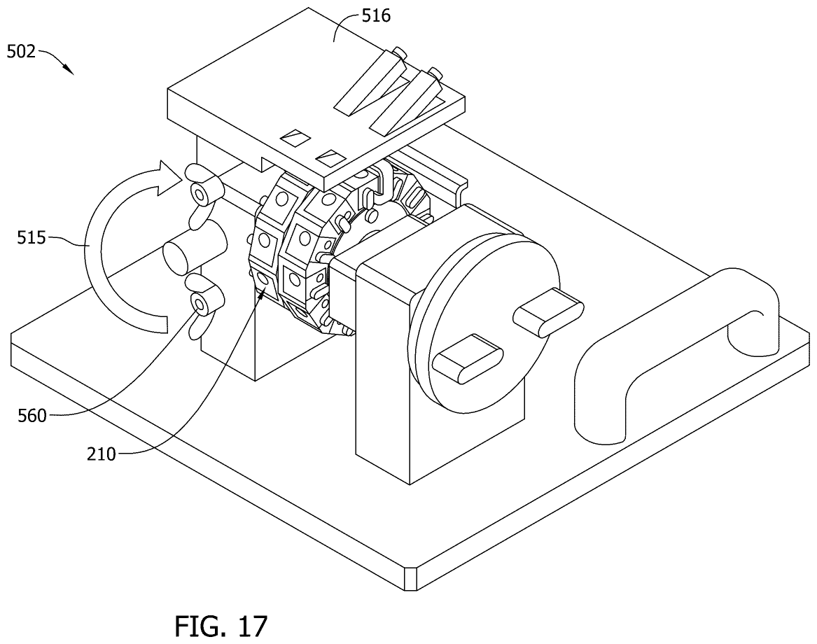

Referring to FIG. 17, at a third step of the installation process, one or more locks 560 are actuated to lock the loading stage 516 in the lowered position, restricting movement of the loading stage 516 during the dopant filling process. In the example embodiment, the one or more locks 560 include a pair of locking knobs 560. The locking knobs 560 are each rotated in the direction 515 to secure the loading stage 516 in the locked position. An uninstallation process of uninstalling the doping hub 210 from the loading assembly 502 can be achieved by reversing the installation process.

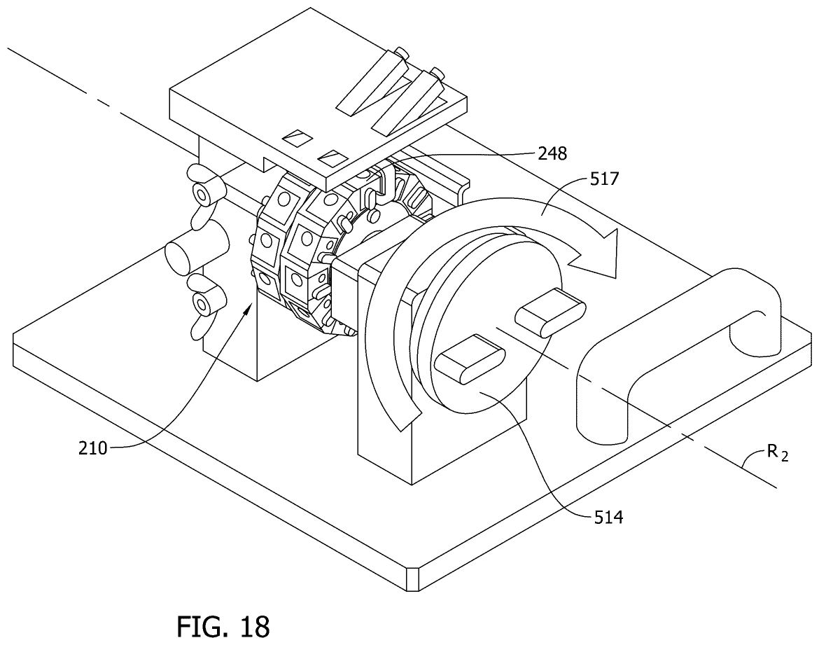

FIGS. 18-20 show a process to load dopant chips into the doping hub 210. Referring to FIG. 18, in a first step, the driving knob 514 is rotated (e.g., manually by an operator) in the direction 517 about the rotational axis R₂. The rotation of the driving knob 514 causes a dopant capsule 248 to be rotated into position below the outlet 528 and for the lid 282 of the dopant capsule 248 to be opened, as shown in FIG. 14. The operator is able to visually observe the opening and positioning of the dopant capsule 248 and thereby guide rotation of the driving knob 514 accordingly.

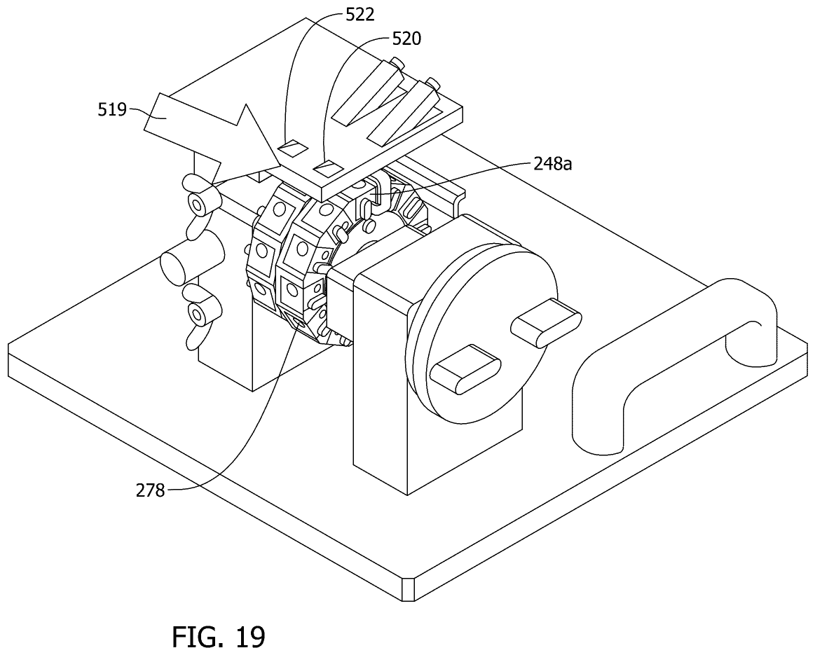

Referring to FIG. 19, at a second step of the installation process, a dopant chip 530 is added to one of the inlets 520, 522 based on which dopant capsule 248 is opened. For example, where the dopant capsule 248a on the second round 278 is opened, as in FIG. 14, a dopant chip 530 is inserted into the first inlet 520 along the direction 519 and is guided by the first channel 526 from the first inlet 520 and to the receptacle 288 of the dopant capsule 248, as described with respect to FIG. 14. In the example embodiments, the dopant chips 530 are each manually loaded into the inlets 520, 522 individually. For example, an operator may use a hand tool, such as but not limited to tweezers, to carry the dopant chips and load the dopant chips into the inlets. In other embodiments, the loading assembly 502 may include one or more dopant banks (not shown) that holds multiple dopant chips and which may be selectively or automatically controlled to release a single dopant chip into the first inlet 520 and/or the second inlet 522.

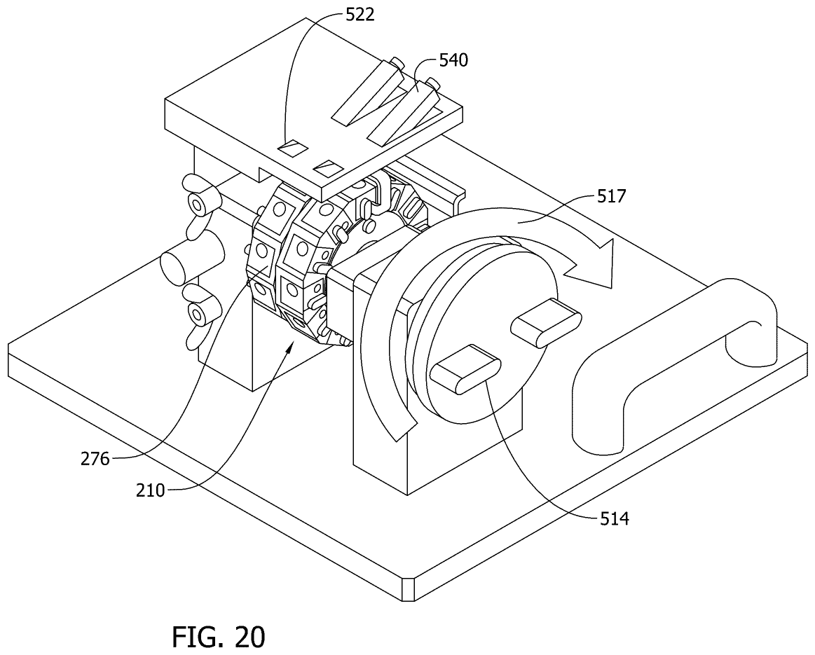

Referring to FIG. 20, after the dopant chip is loaded into the receptacle 288, the driving knob 514 is again rotated in the direction 519. Rotation of the driving knob 514 causes the first closing finger 540 to close the opened dopant capsule 248 and moves another dopant capsule on the first round 276 into alignment with a second outlet of a second channel (not shown) connected with the second inlet 522. The dopant chip 530 may then be loaded into the dopant capsule on the second round 278 by inserting a dopant chip 530 into the second inlet 522. The above steps may be repeated until all dopant capsules 248 on the doping hub 210 are loaded with a dose of dopant.

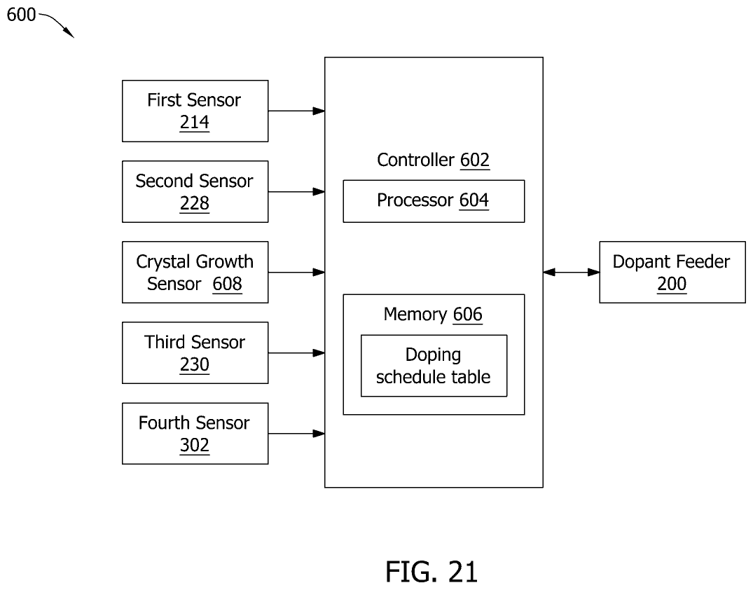

FIG. 21 shows a schematic of a control system 600 for performing an automatic doping operation using the dopant feeder 200, shown in FIGS. 1-11. The control system 600 includes a controller 602 having a processor 604 and a memory 606. The controller 602 may be the same as a controller 602 controlling the ingot puller apparatus 100, shown in FIG. 1, or may be a separate controller 602. The controller 602 is in communication with the first sensor 214, the second sensor 228, the third sensor 230, and the fourth sensor 302. The control system 600 further includes a crystal growth sensor 608.

The crystal growth sensor 608 includes any sensor operable to detect a length of the crystal as it is pulled during the crystal forming process. For example, the crystal growth sensor 608 may include, but is not limited to, one or more of an optical sensor, a weight sensor, and acoustic emission sensors. The controller 602 is in communication with the crystal growth sensor 608 and receives signals from the crystal growth sensor 608 indicating the length of the crystal during the crystal pulling operation.

The controller 602 is in communication with the driving module 204 of the dopant feeder 200 and automatically controls the driving module 204 to release dopant based on the crystal growth detected by the crystal growth sensor 608. In some embodiments, the memory 606 stores one or more doping schedule tables indicating growth lengths of the crystal at which the dopant is to be released into the melt. The doping schedules tables may be fixed tables stored in the memory and/or may be updated by a user for a particular application. As an example, in one embodiment, the doping schedule tables include a first column listing crystal growth lengths and a second column listing a dose of dopant to be released for the corresponding crystal growth rate. The rates may be structured in even increments (e.g., every 100 millimeters) or may be varied depending on the application. When the crystal reaches the corresponding growth length, the controller 602 automatically controls the driving module 204 to perform the corresponding number of rotation increments to release the desired amount of dopant. The controller 602 may further control the driving module 204 based on signals provided from any one of the first sensor 214, the second sensor 228, the third sensor 230, and/or the fourth sensor 302 as described herein.

The controller 602 may be a computer system. Computer systems, as described herein, refer to any known computing device and computer system. As described herein, all such computer systems include a processor and a memory. However, any processor in a computer system referred to herein may also refer to one or more processors wherein the processor may be in one computing device or a plurality of computing devices acting in parallel. Additionally, any memory in a computer device referred to herein may also refer to one or more memories wherein the memories may be in one computing device or a plurality of computing devices acting in parallel. Further, the computer system may located near the apparatus 100 (e.g., in the same room, or in an adjacent room), or may be remotely located and coupled to the rest of the system via a network, such as an Ethernet, the Internet, or the like.

The term processor, as used herein, refers to central processing units, microprocessors, microcontrollers, reduced instruction set circuits (RISC), application specific integrated circuits (ASIC), logic circuits, and any other circuit or processor capable of executing the functions described herein. The above are examples only, and are thus not intended to limit in any way the definition and/or meaning of the term “processor.” The memory may include, but is not limited to, random access memory (RAM) such as dynamic RAM (DRAM) or static RAM (SRAM), read-only memory (ROM), erasable programmable read-only memory (EPROM), electrically erasable programmable read-only memory (EEPROM), and non-volatile RAM (NVRAM).

In one embodiment, a computer program is provided to enable controller 602, and this program is embodied on a computer readable medium. The computer readable medium may include the memory 606 of the controller 602. In an example embodiment, the computer system is executed on a single computer system. Alternatively, the computer system may comprise multiple computer systems, connection to a server computer, a cloud computing environment, or the like. In some embodiments, the computer system includes multiple components distributed among a plurality of computing devices. One or more components may be in the form of computer-executable instructions embodied in a computer-readable medium.

The computer systems and processes are not limited to the specific embodiments described herein. In addition, components of each computer system and each process can be practiced independent and separate from other components and processes described herein. Each component and process also can be used in combination with other assembly packages and processes.

As used herein, the terms “about,” “substantially,” “essentially,” “generally,” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a,” “an,” “the,” and “said” are intended to mean that there are one or more of the elements. The terms “comprising,” “including,” “containing,” and “having” are intended to be inclusive and mean that there may be additional elements other than the listed elements. The use of terms indicating a particular orientation (e.g., “top,” “bottom,” “side,” etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

1-20. (canceled)

21. A loading assembly for loading dopant into a doping hub, the doping hub including a set of doping capsules positioned around an exterior of the doping hub and sized to receive the dopant therein, the loading assembly comprising:
a hub mount for rotatably supporting the doping hub;
a transmission connected to the hub mount for rotating the doping hub within the hub mount; and
a loading stage connected to the hub mount, the loading stage including a channel sized to transmit the dopant through the loading stage and to an outlet, wherein the outlet is positioned to be aligned with each of the doping capsules as the doping hub is rotated within the hub mount for loading dopant into each of the dopant capsules.

22. The loading assembly of claim 21, wherein the hub mount includes a first column and a second column spaced from the first column to receive the doping hub therebetween.

23. The loading assembly of claim 22, wherein the transmission is attached to the first column and the loading stage is attached to the second column.

24. The loading assembly of claim 22, wherein the loading stage is pivotably attached to the second column and moveable between an open position and a closed position, and wherein, in the closed position, the loading stage extends above and at least partially covers the doping hub.

25. The loading assembly of claim 21, wherein the transmission includes a drive and a rotator connected to the drive, the rotator being connectable to the doping hub to support the doping hub in the hub mount and rotate the doping hub relative to the hub mount.

26. The loading assembly of claim 25, wherein the hub mount includes a first column and a second column spaced from the first column, and wherein the drive includes a manually rotatable knob rotatably attached to the first column.

27. The loading assembly of claim 26, wherein the second column defines a recess sized to receive at least a portion of the doping hub therein for supporting the doping hub on the second column, wherein the doping hub defines a rotational axis and wherein the rotational axis extends through the recess and the rotator.

28. The loading assembly of claim 21, wherein the loading stage includes a wall and a slide pivotably attached to the wall, the slide at least partially defining the channel.

29. The loading assembly of claim 21, wherein the loading stage includes a wall and a closing finger pivotably attached to the wall, wherein the closing finger is positioned to close a lid of the dopant capsules after the dopant is loaded into the dopant capsules.

30. The loading assembly of claim 21, wherein the loading stage defines an inlet on an exterior surface of the loading stage, the channel extending from the inlet to the outlet.

31. A dopant loading system comprising:
a doping hub including a set of doping capsules positioned around an exterior of the doping hub, the doping capsules each being sized to receive a dose of dopant; and
a loading assembly comprising:
a hub mount rotatably supporting the doping hub;
a transmission connected to the hub mount for rotating the doping hub within the hub mount; and
a loading stage connected to the hub mount, the loading stage including a channel sized to transmit the dopant through the loading stage and to an outlet, wherein the outlet is positioned to be aligned with each of the doping capsules of the doping hub as the doping hub is rotated within the hub mount for loading dopant into each of the dopant capsules.

32. The dopant loading system of claim 31, wherein the hub mount includes a first column and a second column spaced from the first column to receive the doping hub therebetween.

33. The dopant loading system of claim 32, wherein the transmission is attached to the first column and the loading stage is attached to the second column.

34. The dopant loading system of claim 32, wherein the loading stage is pivotably attached to the second column and moveable between an open position and a closed position, and wherein, in the closed position, the loading stage extends above and at least partially covers the doping hub.

35. The dopant loading system of claim 31, wherein the transmission includes a drive and a rotator connected to the drive, the rotator being connected to the doping hub to support the doping hub in the hub mount and rotate the doping hub relative to the hub mount.

36. The dopant loading system of claim 35, wherein the hub mount includes a first column and a second column spaced from the first column, and wherein the drive includes a manually rotatable knob rotatably attached to the first column.

37. The dopant loading system of claim 36, wherein the second column defines a recess receiving at least a portion of the doping hub therein for supporting the doping hub on the second column, wherein the doping hub defines a rotational axis and wherein the rotational axis extends through the recess and the rotator.

38. The dopant loading system of claim 31, wherein the loading stage includes a wall and a slide pivotably attached to the wall, the slide at least partially defining the channel.

39. The dopant loading system of claim 31, wherein the loading stage includes a wall and a closing finger pivotably attached to the wall, wherein the closing finger is positioned to close a lid of the dopant capsules after the dopant is loaded into the dopant capsules.

40. The dopant loading system of claim 31, wherein the loading stage defines an inlet on an exterior surface of the loading stage, the channel extending from the inlet to the outlet.
